(19) United States
(12) Patent Application Publication
(10) Pub. No.: US 2009/0124097 A1
(43) Pub. Date: May 14, 2009

(54) METHOD OF FORMING NARROW FINS IN FINFET DEVICES WITH REDUCED SPACING THEREBETWEEN

(75) Inventor: Kangguo Cheng, Guilderland, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/937,641

(22) Filed: Nov. 9, 2007

(51) Int. Cl. H01L 21/31

(52) U.S. Cl. 438/792; 438/778; 257/E21.282

(57) ABSTRACT

A method of forming narrow fins in a substrate includes forming a sacrificial mandrel layer over the substrate; using a photolithographic process to pattern the mandrel layer so as to perform a plurality of mandrel features having an initial width greater than or equal to F and spacing therebetween of greater than or equal to F, wherein F corresponds to a minimum feature size associated with the photolithographic process; performing a thermal oxidation of sidewall surfaces of the mandrel features so as to form a plurality of oxide pillars, wherein the thermal oxidation consumes a portion of the mandrel material, and wherein the plurality of oxide pillars have both a width and a spacing therebetween that is less than F; removing remaining portions of the material; and transferring a pattern defined by the oxide pillars into the semiconductor substrate so as to form a plurality of fins having both a width and a spacing therebetween that is less than F.

### BACKGROUND

The present invention relates generally to semiconductor device processing techniques and, more particularly, to a method of forming narrow fins in finFET devices with reduced spacing therebetween.

The escalating demands for high density and performance associated with ultra large scale integrated (ULSI) circuit devices have required certain design features, such as shrinking gate lengths, high reliability and increased manufacturing throughput. The continued reduction of design features has challenged the limitations of conventional fabrication techniques.

For example, when the gate length of conventional planar metal oxide semiconductor field effect transistors (MOSFETs) is scaled below 100 nm, problems associated with short channel effects (e.g., excessive leakage between the source and drain regions) become increasingly difficult to overcome. In addition, mobility degradation and a number of process issues also make it difficult to scale conventional MOSFETs to include increasingly smaller device features. New device structures are therefore being explored to improve FET performance and allow further device scaling.

Double-gate MOSFETs represent one type of structure that has been considered as a candidate for succeeding existing planar MOSFETs. In double-gate MOSFETs, two gates may be used to control short channel effects. A FinFET is a recent double-gate structure that exhibits good short channel behavior, and includes a channel formed in a vertical fine. The FinFET structure may be fabricated using layout and process techniques similar to those used for conventional planar MOSFETs.

However, one of the major challenges associated with forming FinFET structures is the difficulty in making narrow silicon fins with a width smaller than the printing capability of conventional lithography radiation sources. Alternatively, non-conventional approaches, such as e-beam lithography and X-ray lithography, suffer the drawbacks of low throughput and immaturity for manufacturing. On the other hand, a simple spacer imaging technique allows for the formation of fins narrower than the minimal size, F, that can be printed by conventional lithography, but the space between individual fins is still limited by lithography capability. That is, the spacing between individual fins is not also reduced below the minimum feature size so as to allow for increased fin density.

Accordingly, there is a need for a new and improved method of forming semiconductor fins wherein both the fin width and the fin-to-fin spacing are less than a minimal feature size that can be printed by conventional lithography techniques.

### SUMMARY

The foregoing discussed drawbacks and deficiencies of the prior art are overcome or alleviated, in an exemplary embodiment, by a method of forming narrow fins in a semiconductor substrate, the method including forming a sacrificial mandrel layer over the semiconductor substrate; using a photolithographic process to pattern the sacrificial mandrel layer so as to perform a plurality of mandrel features having an initial width greater than or equal to F and spacing therebetween of greater than or equal to F, wherein F corresponds to a minimum feature size associated with the photolithographic process used; performing a thermal oxidation of sidewall surfaces of the mandrel features so as to form a plurality of oxide pillars, wherein the thermal oxidation consumes a portion of the sacrificial mandrel material, and wherein the plurality of oxide pillars have both a width and a spacing therebetween that is less than F; removing remaining portions of the sacrificial material; and transferring a pattern defined by the oxide pillars into the semiconductor substrate so as to form a plurality of semiconductor fins having both a width and a spacing therebetween that is less than F.

In another embodiment, a method of forming narrow fins in a finFET device includes forming a pad layer on a semiconductor-on-insulator (SOI) substrate; forming a sacrificial mandrel layer on the semiconductor substrate; forming a cap layer on the sacrificial mandrel layer; using a photolithographic process to pattern the cap layer and sacrificial mandrel layer so as to perform a plurality of mandrel features having an initial width greater than or equal to F and spacing therebetween of greater than or equal to F, wherein F corresponds to a minimum feature size associated with the photolithographic process used; performing a thermal oxidation of exposed sidewall surfaces of the mandrel features so as to form a plurality of oxide pillars, wherein the thermal oxidation consumes a portion of the sacrificial mandrel material, and wherein the plurality of oxide pillars have both a width and a spacing therebetween that is less than F; removing remaining portions of the sacrificial material and cap layer; and transferring a pattern defined by the oxide pillars into the SOI substrate so as to form a plurality of finFET fins having both a width and a spacing therebetween that is less than F.

### BRIEF DESCRIPTION OF THE DRAWINGS

Referring to the exemplary drawings wherein like elements are numbered alike in the several Figures:

FIGS. 1(a) through 1(f) are a sequence of cross sectional views illustrating a method of forming narrow fins in finFET devices with reduced spacing therebetween, in accordance with an embodiment of the invention.

### DETAILED DESCRIPTION

Disclosed herein is a method of forming narrow fins in finFET devices with reduced spacing therebetween. Briefly stated, the embodiments disclosed herein utilize a sacrificial mandrel layer, such as polysilicon, formed over a semiconductor substrate. The sacrificial mandrel layer is lithographically patterned to form features corresponding to a minimum lithography feature size, F, or greater. The sidewalls of the patterned mandrel layer are then thermally oxidized so as to form a pattern of oxide pillars having a feature size smaller than F. The thermal oxidation process also consumes a portion of the patterned sacrificial mandrel layer such that when the remaining portions of the patterned sacrificial mandrel layer are subsequently removed post-oxidation, the spacing between the oxide pillars is also smaller than F. The resulting pattern defined by the oxide pillars is then transferred onto a substrate so as form narrow fins with sub-F size and spacing therebetween.

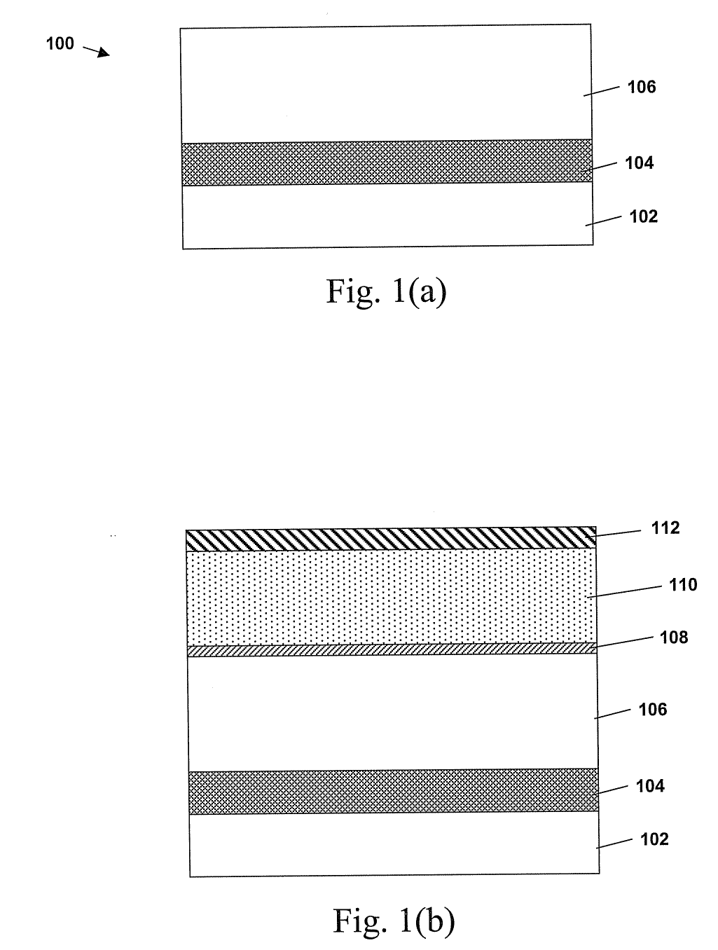

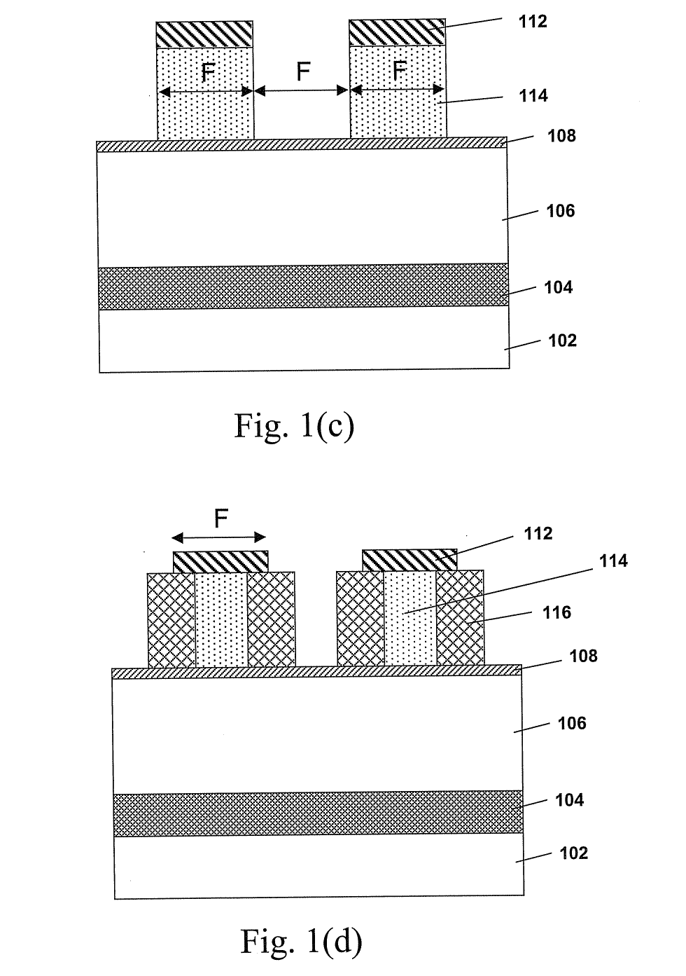

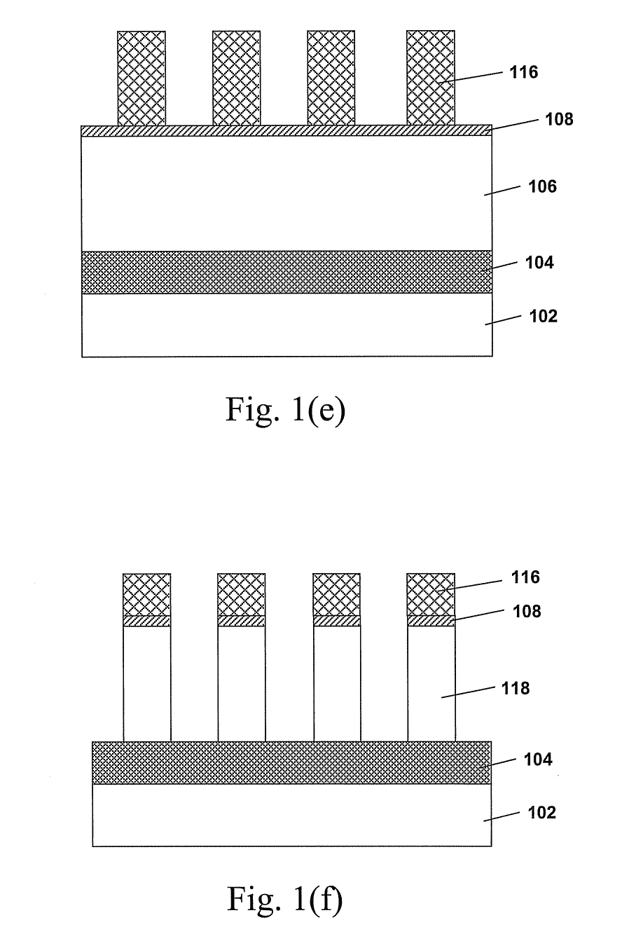

Referring generally to FIGS. 1(a) through 1(f), there is shown a sequence of cross sectional views illustrating a method of forming narrow fins in finFET devices with reduced spacing therebetween, in accordance with an embodiment of the invention. FIG. 1(a) illustrates an exemplary substrate 100 suitable for use in the formation of the fins. In the embodiment depicted, the substrate 100 is a semiconductor-on-insulator (SOI) substrate, including a bulk layer 102, a buried oxide (BOX) layer 104 formed on the bulk layer 102, and an SOI (e.g., silicon, germanium, silicon germanium) layer 106 formed on the BOX layer 104. It should be appreciated, however, that other types of substrates and SOI substrates could also be used in conjunction with the method embodiments disclosed herein. For example, the substrate 100 may be a bulk substrate comprising silicon, germanium, silicon germanium, silicon carbide, or a III-V compound semiconductor (e.g., GaAs), a II-VI compound semiconductors (e.g., ZnSe).

Furthermore, a portion or entire semiconductor substrate may be strained. A portion or entire semiconductor substrate 100 may be amorphous, polycrystalline, or single-crystalline. In addition to the aforementioned types of semiconductor substrates, the semiconductor substrate 100 employed in the present invention may also comprise a hybrid oriented (HOT) semiconductor substrate in which the HOT substrate has surface regions of different crystallographic orientation. The semiconductor substrate 100 may be doped, undoped or contain doped regions and undoped regions therein. The semiconductor substrate 100 may be strained, unstrained, contain regions of strain and no strain therein, or contain regions of tensile strain and compressive strain.

In FIG. 1(b), an optional pad layer 108 (such as silicon nitride) is formed over the SOI layer 106, followed by a sacrificial mandrel layer 110 formed on the pad layer 108. The sacrificial mandrel layer 110 is a material such as polysilicon, for example. However, other materials (e.g., germanium, silicon germanium) may also be used for the sacrificial mandrel layer 110 so long as a portion of the material is consumed during the course of thermal oxidation thereof. As further shown in FIG. 1(b), an optional cap layer 112 (e.g., silicon nitride) is formed over the sacrificial mandrel layer 110.

Referring next to FIG. 1(c), a conventional photolithography and etch process (e.g., reactive ion etch) is used to define mandrel features 114 patterned according to a minimum feature size, F, that is characteristic of the lithography process used. The photolithography process may comprise, for example, introducing electromagnetic radiation such as ultraviolet light through an overlay mask to cure a photoresist material (not shown). Depending upon whether the resist is positive or negative, uncured portions of the resist are removed and exposed portions of the cap layer 112 and sacrificial mandrel layer 110 are etched to form the pattern shown in FIG. 1(c). As indicated above, “F” represents a minimum feature size that may be formed using the specific photolithography technique used. In addition to having a minimum width corresponding to F, the minimum space between adjacent mandrel features 114 is also F.

As then illustrated in FIG. 1(d), a thermal oxidation is then performed so as to grow oxide material on the sidewalls of the mandrel features 114 (i.e., the patterned portions of the sacrificial mandrel layer). Thereby, a plurality of oxide pillars 116 having a width of less than F are defined. Moreover, because the thermal oxidation of the sacrificial mandrel material (e.g., polysilicon) also consumes a portion thereof, the width of the mandrel features 114 shrinks as the oxide pillars 116 are grown. As a result, the spacing between adjacent oxide pillars 116 is also less than F. More specifically, in thermally growing an oxide pillar with a width of t on sidewalls of a polysilicon mandrel feature, about 0.44 t of thickness of the mandrel material is consumed, resulting in the narrower space between the grown oxide pillars. The cap layer 112, if present, prevents the oxidation from the top of the sacrificial mandrel material.

It should be noted at this point that although the example illustrated in FIG. 1(c) depicts mandrel features 114 with an initial width of F and a spacing therebetween of F, this need not be the case. For example, one or both of the mandrel feature width and mandrel feature spacing could be greater than the minimum feature size F. Thus, where the mandrel features have an initial width of 1.05 F (for example) and an initial spacing of 1.02 F therebetween, the subsequently formed oxide pillars will still have both a width and a spacing therebetween that are less than F after thermal oxidation.

In FIG. 1(e), both the cap layer 112 and remaining mandrel structures are stripped by any suitable dry etch or wet etch methods, leaving the narrow oxide pillars 116 with narrow spacing therebetween. When the cap layer comprises silicon nitride, a wet etching solution with an etchant containing hydrofluoric/ethylene glycol (HF/EG) or hot phosphoric acid can be used. Alternatively, a dry etch process such as chemical downstream etch (CDE) or plasma etching can be used to etch silicon nitride. When the remaining mandrel structure comprises polysilicon, a wet etching solution with an etchant containing ammonia can be used. Alternatively, a dry etch process such as chemical downstream etch (CDE) or plasma etching can be used to etch remove polysilicon.

Finally, in FIG. 1(f), the pattern of the oxide pillars 116 is etched through the pad layer 108 and into the SOI layer so as to form the fins 118 with narrow spacing therebetween. As is the case with the oxide pillars, the width of the fins 118 and the space between fins are about half of the lithography minimal feature size F. Thereafter, additional conventional processing may be continued in accordance with finFET techniques.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of forming narrow fins in a semiconductor substrate, the method comprising:
forming a sacrificial mandrel layer over the semiconductor substrate;
using a photolithographic process to pattern the sacrificial mandrel layer so as to perform a plurality of mandrel features having an initial width greater than or equal to F and spacing therebetween of greater than or equal to F, wherein F corresponds to a minimum feature size associated with the photolithographic process used;
performing a thermal oxidation of sidewall surfaces of the mandrel features so as to form a plurality of oxide pillars, wherein the thermal oxidation consumes a portion of the sacrificial mandrel material, and wherein the plurality of oxide pillars have both a width and a spacing therebetween that are less than F;
removing remaining portions of the sacrificial material; and
transferring a pattern defined by the oxide pillars into the semiconductor substrate so as to form a plurality of semiconductor fins having both a width and a spacing therebetween that is less than F.

2. The method of claim 1, wherein the sacrificial layer comprises polysilicon.

3. The method of claim 1, wherein the width of and the spacing between the semiconductor fins is about half of F.

4. The method of claim 1, wherein for the width, t of the plurality of oxide pillars formed by thermal oxidation, about 0.44 t of thickness of the sacrificial mandrel material is consumed.

5. The method of claim 1, wherein the semiconductor substrate is a semiconductor-on-insulator.

6. The method of claim 1, wherein the semiconductor substrate is a bulk substrate.

7. A method of forming narrow fins in a finFET device, the method comprising:
forming a pad layer on a semiconductor-on-insulator (SOI) substrate;
forming a sacrificial mandrel layer on the semiconductor substrate;
forming a cap layer on the sacrificial mandrel layer;
using a photolithographic process to pattern the cap layer and sacrificial mandrel layer so as to perform a plurality of mandrel features having an initial width greater than or equal to F and spacing therebetween of greater than or equal to F, wherein F corresponds to a minimum feature size associated with the photolithographic process used;
performing a thermal oxidation of exposed sidewall surfaces of the mandrel features so as to form a plurality of oxide pillars, wherein the thermal oxidation consumes a portion of the sacrificial mandrel material, and wherein the plurality of oxide pillars have both a width and a spacing therebetween that is less than F;
removing remaining portions of the sacrificial material and cap layer; and
transferring a pattern defined by the oxide pillars into the SOI substrate so as to form a plurality of finFET fins having both a width and a spacing therebetween that is less than F.

8. The method of claim 7, wherein the sacrificial layer comprises polysilicon.

9. The method of claim 7, wherein the width of and the spacing between the semiconductor fins is about half of F.

10. The method of claim 7, wherein for the width, t of the plurality of oxide pillars formed by thermal oxidation, about 0.44 t of thickness of the sacrificial mandrel material is consumed.

11. The method of claim 7, wherein the cap layer is a silicon nitride layer.
